(19) United States
(12) Patent Application Publication
(10) Pub. No.: US 2009/0179308 A1
(43) Pub. Date: Jul. 16, 2009

(54) Method of Manufacturing a Semiconductor Device

(76) Inventor: Chris Stapelmann, Tervuren (BE)

Correspondence Address: SLATER & MATSIL LLP, 17950 PRESTON ROAD, SUITE 1000, DALLAS, TX, 75252, US

(21) Appl. No.: 12/013,923

(22) Filed: Jan. 14, 2008

(51) Int. Cl. H01L 23/58; H01L 21/00; H01L 21/425; H01L 21/8238

(52) U.S. Cl. 257/649; 438/795; 438/530; 438/199; 257/E21.632; 257/E21.473; 257/E21.001; 257/E23.001

(57) ABSTRACT

According to one embodiment of the present invention, a method of manufacturing a semiconductor device is provided. The method includes: forming a semiconductor structure; forming a stress liner over the semiconductor structure; and changing the stress properties of at least a part of the stress liner.

### TECHNICAL FIELD

Embodiments of the present invention generally relate to a method of manufacturing a semiconductor device.

### BACKGROUND

Dual stress liner technology (DSL) is becoming more and more popular for use in deep-submicron technology. Stress liners typically serve for applying mechanical strain upon a structure located adjacent to the stress liners.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a manufacturing stage of a method of manufacturing a semiconductor device according to one embodiment of the present invention;

FIG. 1B shows a schematic cross-sectional view of a manufacturing stage of a method of manufacturing a semiconductor device according to one embodiment of the present invention;

FIG. 1C shows a schematic cross-sectional view of a manufacturing stage of a method of manufacturing a semiconductor device according to one embodiment of the present invention;

FIG. 2 shows a schematic cross-sectional view of a manufacturing stage of a method of manufacturing a semiconductor device according to one embodiment of the present invention;

FIG. 3 shows a schematic cross-sectional view of a manufacturing stage of a method of manufacturing a semiconductor device according to one embodiment of the present invention;

FIG. 4 shows a schematic cross-sectional view of a manufacturing stage of a method of manufacturing a semiconductor device according to one embodiment of the present invention;

FIG. 5 shows a schematic cross-sectional view of a manufacturing stage of a method of manufacturing a semiconductor device according to one embodiment of the present invention;

FIG. 6 shows a schematic cross-sectional view of a manufacturing stage of a method of manufacturing a semiconductor device according to one embodiment of the present invention; and

FIG. 7 shows a schematic cross-sectional view of a manufacturing stage of a method of manufacturing a semiconductor device according to one embodiment of the present invention.

### DETAILED DESCRIPTION OF ILLUSTRATIVE EMBODIMENTS

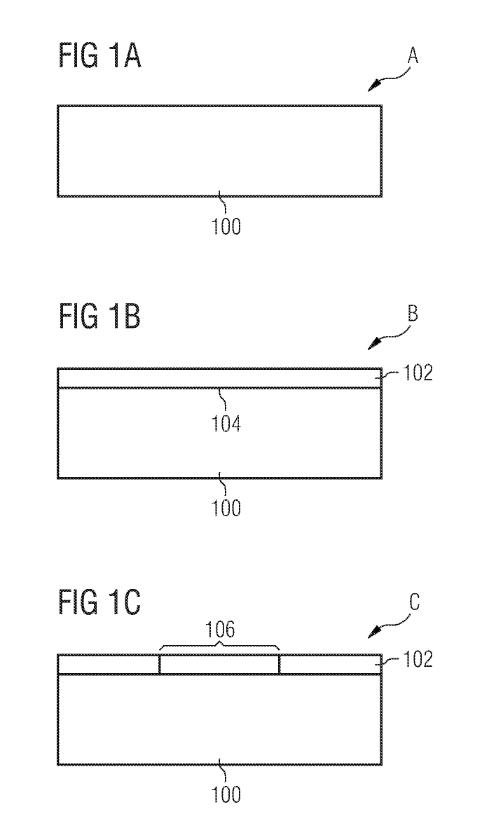

FIG. 1A shows a manufacturing stage A of a semiconductor device obtained after having formed a semiconductor structure 100. The semiconductor structure 100 may, for example, be a silicon substrate. A plurality of n-regions and p-regions (not shown) may be formed in the semiconductor structure 100. Further, conductive elements like select lines or vias and isolation elements (not shown) may be formed on or within the semiconductor structure 100.

FIG. 1B shows a manufacturing stage B obtained after having formed (e.g., deposited) a stress liner 102 over (within the scope of the present invention, the term “a first layer is deposited over a second layer” means that the first layer is directly deposited on the second layer, or that at least one intermediate layer is deposited between the first layer and the second layer) the top surface 104 of the semiconductor structure 100. The stress liner 102 may, for example, be a layer covering the whole top surface 104 of the semiconductor structure 100. However, the stress liner 102 may also be a patterned layer, i.e., may not cover the whole top surface 104 of the semiconductor structure.

FIG. 1C shows a manufacturing stage C obtained after having changed the stress properties of a part 106 of the stress liner 102.

According to one embodiment of the present invention, the stress liner 102 is formed during the manufacturing stage B such that it has compressive stress properties. In this case, the part 106 of the stress liner 102 is treated in manufacturing stage C such that it adopts tensile stress properties.

Alternatively, according to one embodiment of the present invention, the stress liner 102 is formed in manufacturing stage B such that it has tensile stress properties. In this case, the part 106 of the stress liner 102 is treated in manufacturing stage C such that it adopts compressive stress properties.

According to one embodiment of the present invention, one or more electromagnetic wave irradiation processes are carried out in order to change the stress properties of part 106 of the stress liner 102.

According to one embodiment of the present invention, ultraviolet wave irradiation processes are carried out in order to change the stress properties of part 106 of the stress liner 102.

According to one embodiment of the present invention, laser light irradiation processes are carried out in order to change the stress properties of part 106 of the stress liner.

According to one embodiment of the present invention, part 106 of the stress liner 102 is subjected to a chemical treatment in order to change its stress properties.

According to one embodiment of the present invention, part 106 of the stress liner 102 is subjected to an ion implementation process in order to change its stress properties.

According to one embodiment of the present invention, part 106 of the stress liner 102 is subjected to a thermal treatment process in order to change its stress properties.

According to one embodiment of the present invention, part 106 of the stress liner 102 is subjected to a phase transition process in order to change its stress properties.

According to one embodiment of the present invention, the stress liner 102 comprises or consists of, e.g., SiN, SiO₂, SiC, TiN, BN.

According to one embodiment of the present invention, the thickness of the stress liner 102 ranges from about 5 nm to about 200 nm.

According to one embodiment of the present invention, the thickness of the stress liner 102 ranges from about 15 nm to 75 nm. Generally, the liner thickness is depending on the technology used.

According to one embodiment of the present invention, the semiconductor device manufactured is a CMOS device including at least one n-FET (field effect transistor) device and at least one p-FET device (at least a part of the n-FET devices and the p-FET devices may, for example, be formed within the semiconductor structure 100).

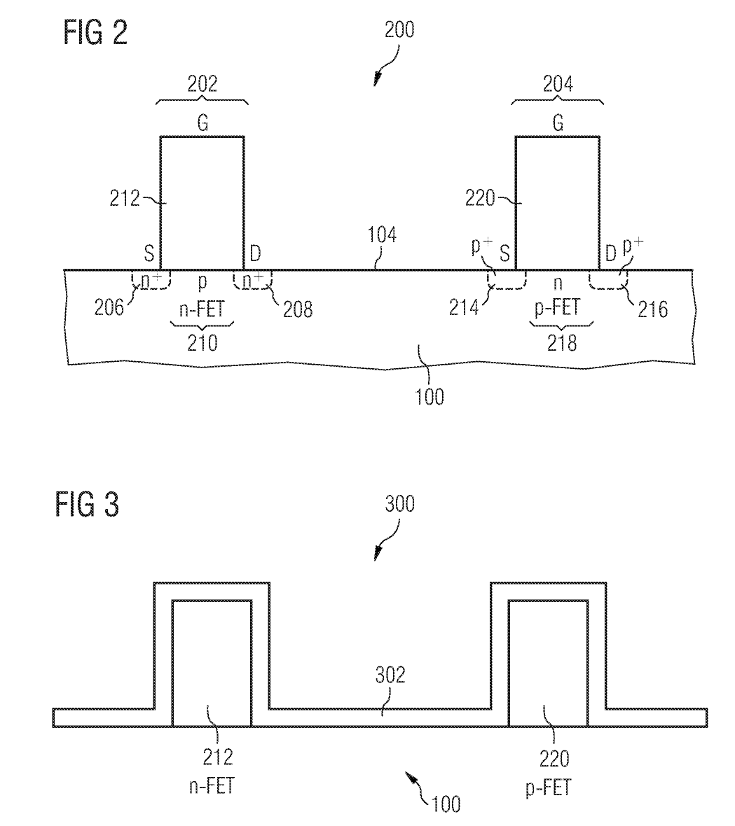

In the following description, making reference to FIGS. 2 to 7, an embodiment of a method of manufacturing a semiconductor device according to the present invention will be explained.

FIG. 2 shows a manufacturing stage 200 obtained after having formed, on/within a semiconductor substrate 100, an n-type field effect transistor 202 and a p-type field effect transistor 204. The n-type field effect transistor 202 includes a n⁺-type source region 206 as well as a n⁻-type drain region 208 and a p-type channel region 210. Further, the n-type field effect transistor 202 includes a gate stack 212 which may, for example, include an isolation layer (not shown) arranged on a top surface 104 of the semiconductor substrate 100, and a conductive element (not shown) arranged on the isolation layer. In the same way, the p-type field effect transistor 204 includes a p⁺-type source region 214, a p⁺-type drain region 216, and an n-type channel region 218. Further, the p-type field effect transistor 204 includes a gate stack 220 having an architecture similar to that described in conjunction with gate stack 212. The gate stacks 212, 220 may respectively comprise a dielectric and at least one of the group of a doped polysilicon electrode, a fully silicided polysilicon electrode, and a metal electrode. However, it is to be understood that the gate stacks 212, 220 may also have different architectures.

FIG. 3 shows a manufacturing stage 300 obtained after having formed a stress liner 302 having compressive stress properties on the top surface 104 of the semiconductor structure 100 as well as on the top surfaces of the gate stacks 212 and 220. The stress liner 302 may, for example, be formed using a PVD process, CVD (epitaxial CVD process, SACVD (Sub-Atmospheric Chemical Vapor Deposition) process, PECVD (Plasma Enhanced Chemical Vapor Deposition) process, LPCVD (Low Pressure Chemical Vapor Deposition) process, HDPCVD (High Density Plasma Vapor Deposition) process, or Flowfill™-CVD process), or a spin-on process.

According to one embodiment of the present invention, the thickness of the stress liner 302 ranges from about 15 nm to about 75 nm

According to one embodiment of the present invention, the stress liner includes or consists of SiN, SiO₂, SiC, TiN, or BN.

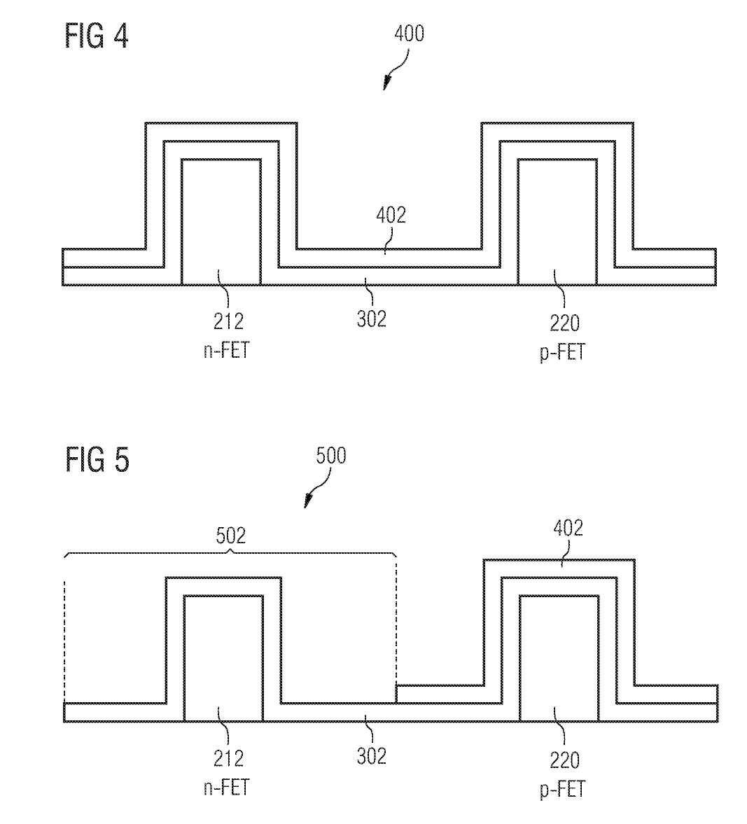

FIG. 4 shows a manufacturing stage 400 obtained after having formed a masking layer 402 on the top surface of the stress liner. The masking layer 402 may, for example, includes or consists of a photoresist, a hard mask, SiO₂, SiN, SiON, or SiC (e.g., amorphous carbon) and may have a thickness ranging from about 5 nm to about 5 μm.

FIG. 5 shows a manufacturing stage 500 obtained after having patterned the masking layer 402, i.e., after having removed the masking layer 402 within a part 502. The removal of the masking layer 402 within part 502 may, for example, be carried out using a lithographic process.

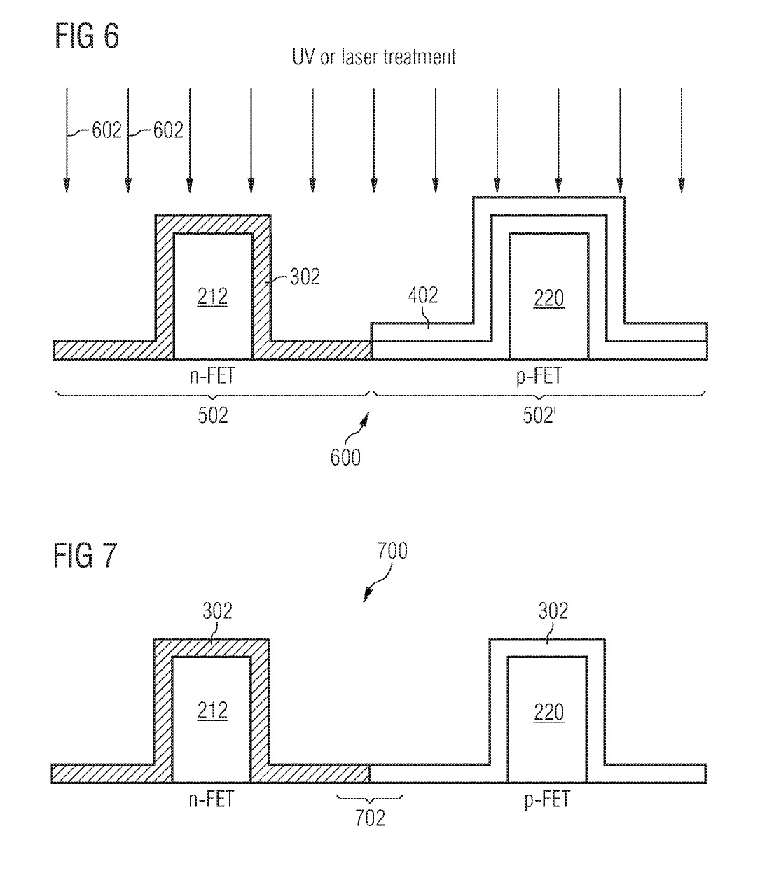

FIG. 6 shows a manufacturing stage 600 obtained after having subjected the top surfaces of the exposed part of the stress liner 302 and the masking layer 402 to an ultraviolet irradiation process or laser treatment process. The light which irradiates the top surfaces of the stress liner 302 and the masking layer 402 is indicated by arrows 602.

The ultraviolet light or the laser light causes the compressive stress properties of the stress liner 302 to change into tensile stress properties (indicated by the hatching) within part 502 which is not covered by the masking layer 402. For example, the material of the masking layer 402 may be chosen such that the ultraviolet light impinging on the masking layer 402 is absorbed or the laser light impinging on the masking layer 402 is reflected. As a consequence, no ultraviolet light/laser light reaches the part 502′ of the stress liner 302 positioned below the masking layer 402. This means that the compressive stress properties of part 502′ of the stress liner 302 are not converted into tensile stress properties. In this way, a stress liner 302 having both compressive stress properties (part 502′) and tensile stress properties (part 502) is obtained.

In one or more embodiments of the invention, the properties of the stress liner may be changed by using a form of energy. Generally, any form of energy may be used. Examples of energy include, but are not limited to, optical energy, electromagnetic energy, electrical energy, ion implantation energy, thermal energy, chemical energy and mechanical (such as acoustic) energy.

According to one embodiment of the present invention, the ultraviolet light/laser light treatment is replaced by a chemical treatment in which chemical substances are brought into contact with the exposed part of the stress liner 302 (i.e., within part 502), whereas the chemical substances are shielded from part 502′ of the stress liner 302 which is located below the masking layer 402.

According to one embodiment of the present invention, the ultraviolet light/laser light treatment is replaced by an ion implantation process in which the exposed part of the stress liner 302 is subjected to ion bombardment. The ion beam may be shielded by the masking layer 402 from impinging onto part 502′ of the stress liner 302. The ions introduced into the film in this manner may be activated by an optional thermal treatment.

It has been assumed in the foregoing description that the exposed part 502 of the stress liner 302 is changed in its stress properties. However, the invention is not restricted thereto. According to one embodiment of the present invention, the exposed part of the stress liner 302 maintains its stress properties, whereas the part 502′of the stress liner 302 located below the masking layer 402 changes its stress properties. For example, the stress properties of the stress liner 302 may be changed using a thermal treatment process. In this case, the material of the masking layer 402 may be chosen such that it absorbs electromagnetic waves (for example, ultraviolet light or laser light) which means that the masking layer 402 converts electromagnetic energy into thermal energy. The thermal energy thus generated then causes the part of the stress liner located below the masking layer 402 to change its stress properties. For example, the thermal energy may cause a phase changing process of part 502′of the stress liner 302, thereby changing its stress properties. In contrast, the material of the stress liner 302 may be chosen to reflect the electromagnetic waves impinging on its top surface. In this way, no or very little heat is generated within the exposed part of the stress liner 302. Thus, no phase transition process is performed within this part of the stress liner 302 which means that the stress properties of part 502 of the stress liner 302 are maintained.

FIG. 7 shows a manufacturing stage 700 in which the patterned masking layer 402 shown in FIG. 6 has been removed. Due to the manufacturing method described above, no overlapping of stress liners of different stress properties occurs within region 702. Further, no gap between stress liners having different stress properties occurs within region 702. In contrast thereto, conventional manufacturing methods either result in an overlap of different stress liners (tensile and compressive stress liner) or result in a gap (no or not enough stress liner material) between different stress liners which can lead to increased complexity or integration problems during subsequent processing such as contact etching.

Thus, according to one embodiment of the present invention, a semiconductor device is provided, comprising: a semiconductor structure 100, a stress liner 302 arranged over the semiconductor structure 100, the stress liner having a compressive stress portion (e.g., part 502′) and a tensile stress portion (e.g. part 502), wherein the compressive stress portion and the tensile stress portion are disposed laterally adjacent to each other such that there is no gap and no overlap between the tensile stress portion and the compressive stress portion.

The stress liner 302 serves for inducing mechanical stress within the channel region 210 and 218, thereby changing the electric (conductive) properties of the channel regions 210 and 218. According to one embodiment of the present invention, the polysilicon contained in the gate stack is changed from a crystalline state to an amorphous state before having reached the manufacturing stage 300. The amorphous polysilicon regions of the gate are re-crystallized again during or after manufacturing stage 600. After this, the stress liner 302 is removed. Due to the phase change of the channel region material between the crystalline state and the amorphous state, the mechanical stress induced into the channel regions 210, 218 remains even after having removed the stress liner 302.

In the following description, further exemplary embodiments of the present invention will be explained.

Dual stress liner technology (DSL) is becoming more and more popular for use in deep sub-micron technology nodes (sub-65 nm). One major issue of DSL is the area where the two liners meet which usually is an overlap area or a gap area. Compared to single stress liner technology, dual stress liner technology requires extra litho steps and layers during manufacturing.

According to one embodiment of the present invention, instead of depositing and partially removing two separate stress liners (one compressive stress liner and one tensile stress liner), only one compressive liner is deposited on both p- and n-FET regions. In the p-FET regions, a protective layer is deposited on top of the compressive liner. The compressive liner in the n-FET region is then exposed to and treated by either a UV cure or a laser anneal to convert the compressive stress into tensile stress. The protective layer on top of the compressive liner in the p-FET regions is either absorbent or reflective for UV cure or reflective for laser anneal. One effect of this embodiment is that process complexity and process costs are reduced.

According to one embodiment of the present invention, the change of stress due to stress liner modification by treatment is used. For the case of using silicon nitride as stress liner material, it has been shown that irradiation such as UV light or heat such as produced by a laser light will break N—H and Si—H bonds inside and release hydrogen from the film (stress liner) causing the film to lose compressive stress and eventually become tensile. By treating only a part of a stress liner, the treated part becomes more tensile. By optimizing the liner chemistry and the treatment, a compressive liner can be transformed into a tensile liner through treatment. By localizing the treatment, only parts of the liner would be converted from compressive to tensile. This mechanism can, for example, be used for either contact etch stop liners (CESL) or SMT (Stress Memory Technique).

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of manufacturing a semiconductor device, comprising:
forming a semiconductor structure;
forming a stress liner having first-type stress properties over the semiconductor structure; and
changing the stress properties of a part of the stress liner to adopt second-type stress properties,
wherein (a) the first-type is compressive stress properties and the second-type is tensile stress properties, or (b) the first-type is tensile stress properties and the second-type is compressive stress properties.

2. The method according to claim 1, wherein changing the stress properties comprises performing an electromagnetic wave irradiation process.

3. The method according to claim 2, wherein changing the stress properties comprises performing an ultraviolet wave irradiation process.

4. The method according to claim 2, wherein changing the stress properties comprises performing a laser light irradiation process.

5. The method according to claim 1, wherein changing the stress properties comprises performing a chemical treatment of the stress liner.

6. The method according to claim 1, wherein changing the stress properties comprises subjecting the stress liner to an ion implementation process.

7. The method according to claim 6, further comprising subjecting the stress liner to a heat treatment after the ion implementation process.

8. The method according to claim 1, wherein changing the stress properties comprises subjecting the stress liner to a thermal treatment process.

9. The method according to claim 1, further comprising before changing the stress properties of the stress liner, forming a patterned masking layer over the stress liner.

10. The method according to claim 9, wherein the patterned masking layer reflects electromagnetic waves impinging on the patterned masking layer.

11. The method according to claim 9, wherein the patterned masking layer absorbs electromagnetic waves impinging on the patterned masking layer.

12. The method according to claim 9, wherein the patterned masking layer prevents chemical substances from chemically reacting with parts of the stress liner located below the patterned masking layer.

13. The method according to claim 9, wherein the patterned masking layer prevents ions from impinging on the patterned masking layer from reaching parts of the stress liner located below the patterned masking layer.

14. The method according to claim 9, further comprising removing the patterned masking layer after a treatment of the stress liner has been performed.

15. The method according to claim 1, wherein the stress liner is formed over semiconductor channel regions of transistors formed within the semiconductor structure and treated after the formation such that mechanical strain occurring within the semiconductor channel regions is increased or decreased by the change of stress of the stress liner.

16. The method according to claim 15, wherein the semiconductor structure comprises p-type channel regions and n-type channel regions, wherein the stress liner is formed over the channel regions and treated after the formation such that mechanical strain is increased within p-type channel regions, and is decreased within n-type channel regions.

17. The method according to claim 15, wherein the stress liner is arranged over gates of the transistors.

18. The method according to claim 1, wherein the stress liner is formed over a semiconductor structure containing amorphous material and, after having deposited the stress liner, the amorphous material is changed to a crystalline state.

19. The method according to claim 18, wherein the stress liner is formed over a gate electrode comprising a polysilicon layer, a metal layer, or a fully silicided (FUSI) layer.

20. The method according to claim 18, further comprising removing the stress liner after having changed stress properties of a part of the stress liner, and after having changed the amorphous material to crystalline material.

21. The method according to claim 1, wherein the stress liner comprises silicon nitride.

22. The method according to claim 1, wherein the semiconductor device comprises a CMOS device comprising a n-FET device and a p-FET device.

23. The method according to claim 1, wherein the stress liner has a thickness between about 5 nm and about 200 nm.

24. A semiconductor device, comprising:
a semiconductor structure;
a stress liner arranged over the semiconductor structure, the stress liner having a compressive stress portion and a tensile stress portion,
wherein the compressive stress portion and the tensile stress portion are disposed laterally adjacent to each other such that there is no gap and no overlap between the tensile stress portion and the compressive stress portion.

25. The semiconductor device according to claim 24, wherein the stress liner comprises silicon nitride.
